(19) United States
(12) Patent Application Publication
(10) Pub. No.: US 2025/0071918 A1
(43) Pub. Date: Feb. 27, 2025

(54) DISPLAY DEVICE INCLUDING HINGE DEVICE FOR CONTROLLING STATE THEREOF

(71) Applicant: LG DISPLAY CO., LTD., Seoul (KR)

(72) Inventor: ChounSung KANG, Gimpo-si (KR)

(73) Assignee: LG DISPLAY CO., LTD., Seoul (KR)

(21) Appl. No.: 18/779,861

(22) Filed: Jul. 22, 2024

(30) Foreign Application Priority Data
Aug. 21, 2023 (KR) 10-2023-0109053

(51) Int. Cl. H05K 5/02; F16C 11/04

(52) U.S. Cl. CPC H05K 5/0226; F16C 11/04; H05K 5/023

(57) ABSTRACT

A display device according to an aspect of the present disclosure may include a display module; and a hinge component configured to enable the display module to switch between being in a flat state or a curved state. The hinge component includes at least one hinge frame; at least one hinge component around which the at least one hinge frame is configured to rotate to allow the display module to switch between the flat state and the curved state; and at least one stopper at each of two ends of the hinge component configured to maintain the display module in the flat state, the curved state, or an intermediary state in between the flat state and the curved state.

### CROSS-REFERENCE TO RELATED APPLICATIONS

This application claims the priority of Korean Patent Application No. 10-2023-0109053 filed on Aug. 21, 2023, in the Korean Intellectual Property Office, the disclosure of which is incorporated herein by reference.

### BACKGROUND

### Field of Disclosure

The present disclosure relates to a display device, and more particularly, to a bendable display device.

### Description Of Related Background

In general, examples of flat display devices include liquid crystal display devices, plasma display devices, field emission display devices, light-emitting display devices. The liquid crystal display device and the light-emitting display device are in the limelight because the liquid crystal display device and the light-emitting display device have advantages in mass-production technologies, ease of operations, and implementation of high image quality.

Recently, there has been a particular need for research and development on technical aspects of flat display devices, as well as research and development on the design of products to make the products more appealing to customers. Therefore, there has been a gradual increase in the need for curved display devices with curvatures.

In particular, recently panels have gradually become larger in size. Accordingly, the development is being conducted on innovative curvature-changeable display devices with slimness required by consumers.

### SUMMARY

An example objective of the present disclosure is to provide a display device capable of allowing a user to arbitrarily change curvatures between a flat display mode and a curved display mode.

Another example objective of the present disclosure is to provide a display device capable of stably maintaining a curvature in a curved display mode.

The concepts described herein are not limited to example objectives mentioned above and may encompass other objectives as understood by those skilled in the art from the following descriptions.

Other detailed matters of the exemplary embodiments are included in the detailed description and the drawings.

The present disclosure may provide the display device capable of allowing the user to arbitrarily change the curvature between the flat display mode and the curved display mode.

The present disclosure may provide the display device capable of being stably maintaining the curvature while suppressing noise and abrasion of the constituent components caused by repeated bending.

In one aspect, a display device includes a display module; and a hinge component configured to enable the display module to switch between being in a flat state or a curved state. The hinge component includes at least one hinge frame; at least one hinge component around which the at least one hinge frame is configured to rotate to allow the display module to switch between the flat state and the curved state; and at least one stopper at each of two ends of the hinge component configured to maintain the display module in the flat state, the curved state, or an intermediary state in between the flat state and the curved state.

In another aspect, the display device further includes a pair of bolt and nut for each of the at least one hinge component, the pair of bolt and nut being configured to allow for adjustment of torque applied for maintaining the flat state, the curved state, and the intermediary state.

In another aspect, the at least one stopper includes a pair of a lower stopper and an upper stopper.

In another aspect, each of the lower stopper and the upper stopper includes a fixing portion; and a slit, wherein the slit and the fixing portion are configured to maintain the display module in the flat state, the curved state, or the intermediary state in between the flat state and the curved state.

In another aspect, the slit has an elongated semi-circular shape.

In another aspect, the fixing portion is configured to move in a first direction that is perpendicular to a direction in which the display module moves between the flat state and the curved state.

In another aspect, the display device further includes an embossed portion, wherein the slit is formed around the embossed portion.

In another aspect, the fixing portion and the embossed portion are configured to move in a first direction that is perpendicular to a direction in which the display module moves between the flat state and the curved state.

In another aspect, the at least one hinge frame includes multiple independently movable hinge frames each of which can rotate around one or more of the at least one hinge component to enable the display module to switch between the flat state and the curved state.

In another aspect, the display device further includes a hinge cover configured to cover the hinge component; and a pair of handles, each of which is coupled to one end of the hinge cover for moving the display module between the flat state and the curved state.

In one aspect, a device includes a plurality of parts coupled together via a plurality of hinges to enable moving a display module between a flat state and a curved state, wherein the plurality of parts are independently movable; and at least one stopper attached to the plurality of parts, the at least one stopper being configured to maintain the display module in the flat state, the curved state, or an intermediary state in between the flat state and the curved state.

In another aspect, the plurality of parts includes a first part at a right end of the device; a second part at a left end of the device; a middle part at a center of the device; a third part between the middle part and the first part; and a fourth part between the middle part and the second part.

In another aspect, the at least one stopper includes a first stopper attached to the first part; a second stopper attached to the second part; a third stopper attached to the third part; and a fourth stopper attached to the fourth part.

In another aspect, each of the first stopper, the second stopper, the third stopper, and the fourth stopper includes a pair of stoppers.

In another aspect, the at least one stopper is formed as an extension of a respective outer end of each of the first part and the second part.

In another aspect, the respective outer end is bent to form the at least one stopper.

In another aspect, the at least one stopper includes a slit formed on the at least one stopper; and a fixing portion surrounded by the slit and configured to move in a first direction that is perpendicular to a direction in which the display module moves between the flat state and the curved state.

In another aspect, the device is coupled to a backend of the display module to move the display module between the flat state and the curved state.

In another aspect, a pair of handles are attached to ends of the device to enable moving the display module between the flat state and the curved state.

In another aspect, the device is coupled to a stand for holding the display module.

In another aspect, the lower stopper and the upper stopper have a horizontally symmetric structure, and wherein the pair of stoppers has a vertically symmetry with respect to at least one other pair of stoppers of the hinge component.

In another aspect, an outer end of the first part is bent upward and downward to define a pair of support portions, wherein each support portion of the pair of support portions has a rectangular shape, and wherein a first slot is formed in the support portion and has a shape elongated in a longitudinal direction.

In another aspect, a polymer plate is disposed on an upper portion of the support portion, and the at least one stopper is disposed on an upper portion of the polymer plate.

In another aspect, the polymer plate has a rectangular shape, and a second slot is formed in the polymer plate and has a shape elongated in a longitudinal direction, wherein the second slot is positioned to correspond to the first slot, and wherein the second slot is larger in size than the first slot.

In another aspect, circular first holes are provided in the polymer plate and disposed at predetermined intervals in a longitudinal direction to define the second slot, wherein the second slot includes the circular first holes and a plurality of second holes provided between the plurality of first holes, and wherein the second hole has a smaller width than the first hole.

In another aspect, in case of the curved state, an embossed portion is positioned in the first hole in a predetermined curvature state, such that the embossed portion is inserted and fixed into the first hole, and wherein in case the flat state or the intermediary state is implemented, the embossed portion is positioned in the second hole, such that the embossed portion is lifted upward and positioned on the polymer plate without being inserted and fixed into the second hole.

In another aspect, the device further includes a link attached to upper portions of the pair of stoppers in a direction in which the link traverses the pair of stoppers, wherein the link is attached to the upper portion of the fixing portion opposite to the embossed portion.

In another aspect, the device further includes a plurality of protruding structures protruding from a rear surface of the display module, wherein insertion holes are provided at two opposite ends of the link, and the protruding structures are inserted into the insertion holes.

In another aspect, the protruding structure is disposed on the rear surface of the display module and has a height to a degree to which the protruding structure penetrates the insertion hole, and wherein the plurality of protruding structures is disposed at intervals between the plurality of first holes.

According to the present disclosure, the protruding structure, the display cover, the stopper, and the third hinge frame may be integrated, like a unified material. Therefore, the component material may be simplified and unified.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a block diagram illustrating a display device according to some aspects of the present disclosure;

FIG. 2 is a block diagram schematically illustrating a display module in FIG. 1 according to some aspects of the present disclosure;

FIG. 3 is a perspective view illustrating a display device according to according to some aspects of the present disclosure;

FIG. 4 is a rear view illustrating the display device according to according to some aspects of the present disclosure;

FIG. 5 is a perspective view illustrating a hinge unit in FIG. 4;

FIG. 6 is a view exemplarily illustrating free-stop bending made by the hinge unit according to some aspects of the present disclosure;

FIG. 7 is an enlarged view of a first hinge part in FIG. 5 according to some aspects of the present disclosure;

FIG. 8 is a view illustrating a part of a cross-section of the first hinge part in FIG. 7 according to some aspects of the present disclosure;

FIGS. 9A to 9C are enlarged view of part A in FIG. 4 according to some aspects of the present disclosure;

FIGS. 10A to 10C are enlarged perspective views of part A in FIG. 4 according to some aspects of the present disclosure;

FIGS. 11A to 11C are views illustrating part A in FIG. 4 when viewed from the lateral side according to some aspects of the present disclosure;

FIG. 12A is an enlarged view of part B in FIG. 9C according to some aspects of the present disclosure;

FIG. 12B is a view illustrating a cross-section taken along line C-C′ in FIG. 12A according to some aspects of the present disclosure;

FIG. 13A is an enlarged view of part B in FIG. 9C according to some aspects of the present disclosure;

FIG. 13B is a view illustrating a cross-section taken along line D-D′ in FIG. 13A according to some aspects of the present disclosure;

FIGS. 14A and 14B are views illustrating simulation results showing examples of equivalent stress of a comparative example according to some aspects of the present disclosure;

FIGS. 15A and 15B are views illustrating simulation results showing examples of equivalent stress of a comparative example according to some aspects of the present disclosure;

FIG. 16 is a rear view illustrating a display device according to according to some aspects of the present disclosure;

FIG. 17 is a rear view illustrating a display device according to according to some aspects of the present disclosure;

FIGS. 18A and 18B are rear views illustrating a part of a rear surface of the display device according to some aspects of the present disclosure; and

FIGS. 19A and 19B are perspective views illustrating a part of the rear surface of the display device according to some aspects of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art may fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure may be partially or entirely adhered to or combined with each other and may be interlocked and operated in technically various ways, and the embodiments may be carried out independently of or in association with each other.

Hereinafter, an exemplary aspect of the present disclosure will be described in detail with reference to the drawings.

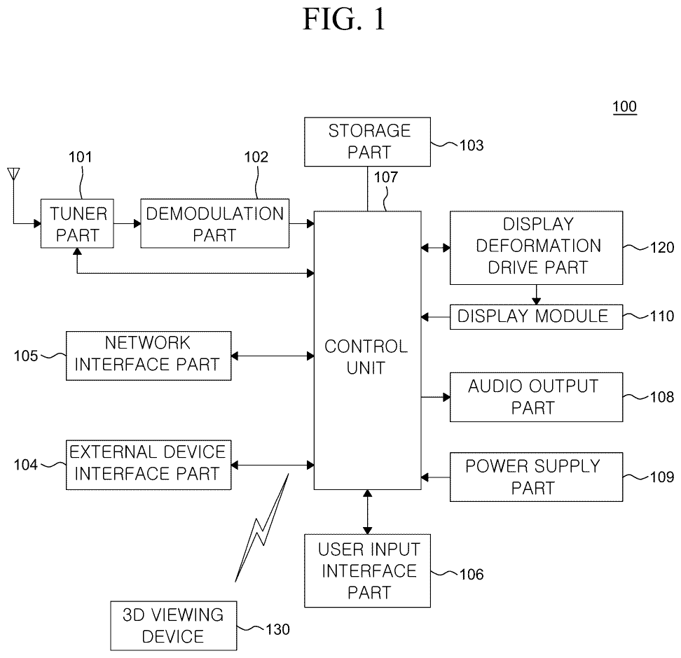

FIG. 1 is a block diagram illustrating a display device according to some aspects of the present disclosure.

With reference to FIG. 1, a display device 100 may include a tuner part 101, a demodulation part 102, a storage part 103, an external device interface part 104, a network interface part 105, a user input interface part 106, and a control unit 107.

In addition, the display device 100 may include a display module 110, a display deformation drive part 120, an audio output part 108, and a power supply part 109.

Further, the display device 100 may further include a 3D viewing device 130. However, the present disclosure is not limited thereto. In some instances, the 3D viewing device 130 may not be included.

The tuner part 101 may select a radio frequency (RF) broadcast signal, which corresponds to a channel selected by a user or all pre-stored channels, from RF broadcast signals received through an antenna. In addition, the tuner part may convert the selected RF broadcast signal into an intermediate frequency signal, a baseband image, or a voice signal.

For example, when the selected RF broadcast signal is a digital broadcast signal, the selected RF broadcast signal may be converted into a digital IF signal (DIF). When the selected RF broadcast signal is an analog broadcast signal, the selected RF broadcast signal may be converted into an analog baseband image or a voice signal (CVBS/SIF). That is, the tuner part 101 may process the digital broadcast signal or the analog broadcast signal. The analog baseband image or voice signal (CVBS/SIF) outputted from the tuner part 101 may be inputted directly to the control unit 107.

In addition, the tuner part 101 may receive a RF broadcast signal of a single carrier according to the advanced television system committee (ATSC) method or receive RF broadcast signals of a plurality of carriers according to the digital video broadcasting (DVB) method.

The demodulation part 102 may receive the digital IF signal (DIF), which is converted by the tuner part 101, and perform a demodulation operation.

For example, in case that the digital IF signal outputted from the tuner part 101 is the ATSC type, the demodulation part 102 performs 8-vestigial side band (8-VSB) demodulation. In addition, the demodulation part 102 may also perform channel decryption.

In addition, for example, when the digital IF signal outputted from the tuner part 101 is the DVB type, the demodulation part 102 may perform coded orthogonal frequency division modulation (COFDMA). In addition, the demodulation part 102 may also perform channel decryption.

In addition, the demodulation part 102 may output a stream signal (TS) after performing the demodulation and the channel decryption.

Meanwhile, the demodulation parts 102 may be separately provided as an ATSC type demodulation part and a DVB type demodulation part. For example, an ATSC demodulation part and a DVB demodulation part may be provided.

The stream signal outputted from the demodulation part 102 may be inputted to the control unit 107.

After the control unit 107 performs demultiplexing, image/voice signal processing, and the like, the control unit 107 may output an image to the display module 110 and output a voice to the audio output part 108.

The external device interface part 104 may connect an external device and the display device 100. To this end, the external device interface part 104 may include an A/V input/output part (not illustrated) or a wireless communication part (not illustrated).

The external device interface part 104 may be connected to external devices, such as digital versatile disks (DVDs), Blu rays, gaming devices, cameras, camcorders, computers, and the like in a wired/wireless manner. For example, the external device interface part 104 may transmit images, voices, or data signals, which are inputted from the outside through the connected external device, to the control unit 107 of the display device 100.

In addition, images, voices, or data signals processed by the control unit 107 may be outputted to the connected external device. To this end, the external device interface part 104 may include the A/V input/output part or the wireless communication part.

The external device interface part 104 may transmit and receive data to and from the 3D viewing device 130.

The network interface part 105 may provide an interface for connecting the display device 100 to wired/wireless networks including the Internet. The network interface part 105 may be equipped with an Ethernet terminal or the like to be connected to the wired network. The network interface part 105 may use wireless LAN (WLAN), wireless broadband (Wibro), world interoperability for microwave access (WiMAX), and high-speed downlink packet access (HSDPA) communication standards to be connected to the wireless network.

In addition, the network interface part 105 may receive, through the network, content or data provided by the Internet, a content provider, or a network operator.

The storage part 103 may store programs for processing and controlling signals in the control unit 107 or store signal-processed images, voices, or data signals.

In addition, the storage part 103 may serve to temporarily store images, voices, or data signals to be inputted to the external device interface part 104. The storage part 103 may also store information on a predetermined broadcast channel through a channel memory function such as a channel map.

FIG. 1 illustrates an aspect in which the storage part 103 and the control unit 107 are separately provided. However, the scope of the present disclosure is not limited thereto. The storage part 103 may be included in the control unit 107.

The user input interface part 106 may transmit a signal, which is inputted by the user, to the control unit 107 or transmit a signal from the control unit 107 to the user.

For example, the user input interface part 106 may receive user input signals, such as power on/off, channel selection, and screen configurations, from a remote control device or transmit signals from the control unit 107 to the remote control device in accordance with various communication methods such as a radio frequency (RF) communication method or an infrared (IR) communication method.

The control unit 107 may use the tuner part 101, the demodulation part 102, and the external device interface part 104 to generate and output signals for outputting images or voices by demultiplexing the inputted stream signals or processing demultiplexed signals.

In addition, image signals processed by the control unit 107 may be inputted to the display module 110, such that images corresponding to the corresponding image signals may be displayed. The image signal processed by the control unit 107 may be inputted to an external output device through the external device interface part 104.

The voice signal processed by the control unit 107 may be outputted as a sound to the audio output part 108. The voice signal processed by the control unit 107 may be inputted to the external output device through the external device interface part 104.

In addition, the control unit 107 may control overall operations of the display device 100.

The display module 110 may generate driving signals by converting an image signal, a data signal, an OSD signal, a control signal, and the like, which are processed by the control unit 107 or converting an image signal, a data signal, a control signal, and the like received by the external device interface part 104.

Aspects of the present disclosure provide examples in which the display device 100 may be deformed to have the display module 110 in a flat state, i.e., a flat display mode, or a curved state, i.e., a curved display mode. In case that the display module 110 is deformed to be in the curved state (or curved surface state) as if the display module 110 surrounds the user positioned in front of the display module 110, the display module 110 may provide the user with realistic image quality and immersion. For example, the display device 100 may be implemented by an OLED panel. However, the present disclosure is not limited thereto.

The display module 110 may be configured to provide a three-dimensional image to the user. For viewing three-dimensional images, the display module 110 may be classified into an additional display type display module and a single display type display module.

The single display type display module 110 may implement 3D images without the separate 3D viewing device 130, for example, via 3D glasses or the like (e.g., various modules, such as a lenticular type or a parallax barrier, may be applied).

The additional display type display module may implement 3D images by using the 3D viewing device 130 in addition to the display module 110. For example, various modules, such as a head mount display (HMD) type or a glass type, may be applied.

Meanwhile, the display module 110 may include a touch screen and can be used as an input device as well as an output device.

The display deformation drive part 120 may be configured to deform the display module 110 in a flat state or a curved state (or curved surface state).

In the present disclosure, the curvature of the display module 110 may be arbitrarily changed between the flat display mode and the curved display mode. In the flat display mode, the display module 110 may be implemented in a flat state. In the curved display mode, the display module 110 may be implemented in a curved state.

For example, the display deformation drive part 120 may be configured to deform the display module 110 by applying a physical force directly or indirectly to the display module 110.

The audio output part 108 may receive a signal processed by the control unit 107, e.g., a stereo signal, a 3.1-channel signal, or a 5.1-channel signal and output a voice. The audio output part 108 may be implemented as various types of speakers.

The power supply part 109 may supply corresponding power to the overall components of the display device 100.

Examples of the display device 100 disclosed in the present disclosure may include a TV set, a mobile phone, a smartphone, a notebook computer, a digital broadcast terminal, a personal digital assistant (PDA), a portable multimedia player (PMP), and the like.

A block diagram of the display device 100 illustrated in FIG. 1 is a block diagram for different aspects of the present disclosure described below. Therefore, the constituent elements in the block diagram may be integrated, added, or excluded depending on the specifications of the display device 100 implemented. For example, as necessary, two or more constituent elements may be integrated into a single constituent element, or one constituent element may be divided into two or more constituent elements. In addition, the functions, which are performed in each block, are provided to explain the embodiments of the present disclosure. The specific operations or devices do not limit the protection scope of the present disclosure.

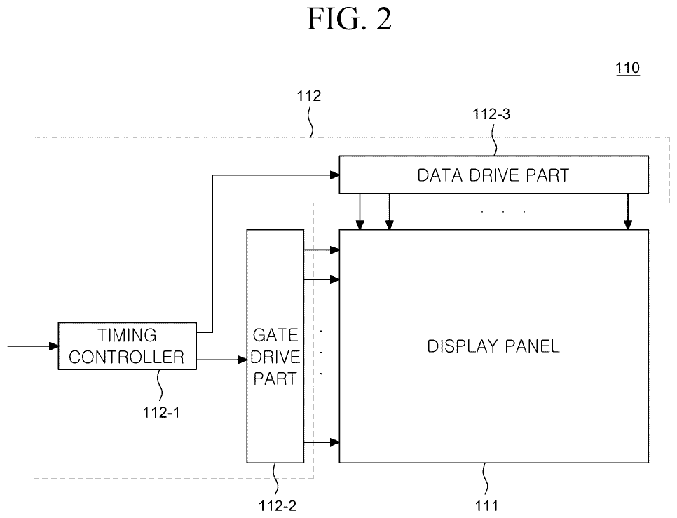

FIG. 2 is a block diagram schematically illustrating the display module in FIG. 1 according to some aspects of the present disclosure.

With reference to FIG. 2, the display module 110 may include a display panel 111 including a plurality of subpixels, and a drive circuit part 112 configured to supply various types of signals to the display panel 111.

The display panel 111 may be configured to display images to the user and include a plurality of subpixels SP. In the display panel 111, the plurality of scan lines SL and the plurality of data lines DL may intersect one another, and each of the plurality of subpixels SP may be connected to the scan line SL and the data line DL. In addition, the plurality of subpixels SP may each be connected to a high-potential power line, a low-potential power line, a reference line, or the like. However, the present disclosure is not limited thereto.

The display panel 111 may have a display area, and a non-display area configured to surround the display area.

The display area is an area of the display panel 111 in which images are displayed.

The display area may include a plurality of subpixels configured to constitute a plurality of pixels, and a circuit configured to operate the plurality of subpixels. The plurality of subpixels is minimum units that constitute the display area. The n subpixels may constitute a single pixel. All types of display panels, such as liquid crystal display panels, organic electroluminescent display panels, quantum dot display panels, and electroluminescent display panels, may be used as the display panel 111 are within the scope of the present disclosure.

The non-display area is an area in which no image is displayed. The non-display area may be defined as an area extending from the display area. The non-display area may include link lines and pad electrodes for transmitting signals to the subpixels in the display area. Alternatively, the non-display area may include drive ICs such as gate drivers IC and data drivers IC.

The drive circuit part 112 operates the display panel 111 in response to a control signal supplied from the control unit 107 in FIG. 1. To this end, the drive circuit part 112 may include a timing controller 112-1, a gate drive part 112-2, and a data drive part 112-3.

For example, the gate drive part 112-2 may supply a plurality of scan signals to the plurality of scan lines in response to a plurality of gate control signals provided from the timing controller 112-1. FIG. 2 illustrates that the single gate drive part 112-2 is disposed to be spaced apart from the left side of the display panel 111. However, the number and arrangement of the gate drive part 112-2 are not limited thereto.

For example, the data drive part 112-3 may convert image data, which are inputted from the timing controller 112-1, into a data voltage by using a reference gamma voltage in response to a plurality of data control signals provided from the timing controller 112-1. The data drive part 112-3 may supply the converted data voltage to the plurality of data lines.

In addition, the timing controller 112-1 may align image data, which are inputted from the outside, and supply the image data to the data drive part 112-3. The timing controller 112-1 may generate the gate control signals and the data control signals by using synchronizing signals, i.e., dot clock signals, data enable signals, and horizontal/vertical synchronizing signals inputted from the outside. Further, the timing controller 112-1 may control the gate drive part 112-2 and the data drive part 112-3 by supplying the generated gate control signals and data control signals to the gate drive part 112-2 and the data drive part 112-3.

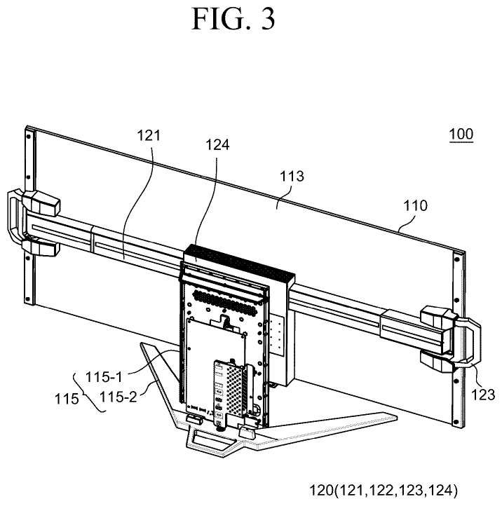

FIG. 3 is a perspective view illustrating a display device according to some aspects of the present disclosure.

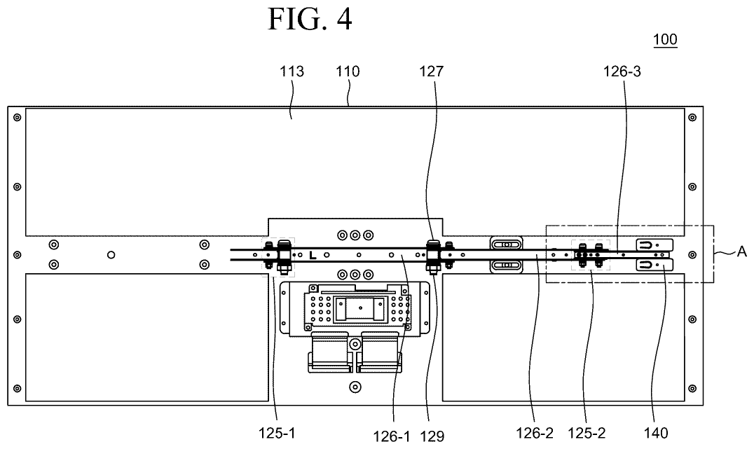

FIG. 4 is a rear view illustrating the display device according to some aspects of the present disclosure.

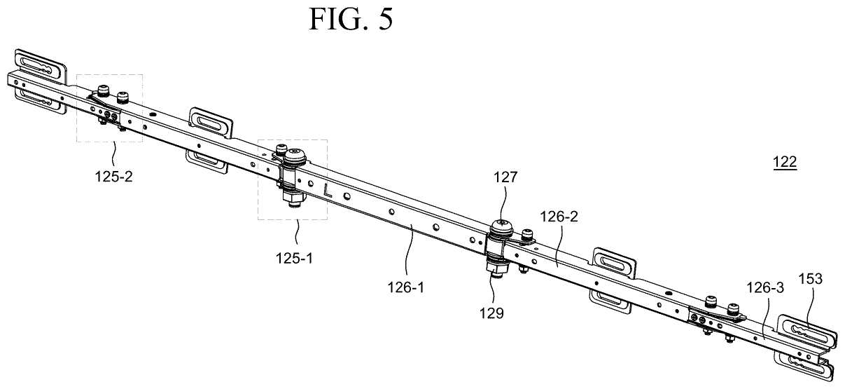

FIG. 5 is a perspective view illustrating a hinge unit in FIG. 4 according to some aspects of the present disclosure.

FIG. 3 is a perspective view illustrating a rear surface of the display device 100 according to some aspects of the present disclosure including a stand 115, a hinge cover 121, and a stand fastening part 124.

FIG. 4 is a view illustrating the rear surface of the display device 100 according to the first aspect of the present disclosure that does not include the stand 115, the hinge cover 121, and the stand fastening part 124. For convenience of description, FIG. 4 illustrates a state in which the left side of a hinge unit 122 is excluded. A hinge unit may also be referred to as a hinge device.

With reference to FIGS. 3 to 5, the display device 100 may include the display module 110, the stand 115, and the display deformation drive part 120.

The display deformation drive part 120 may include the hinge unit 122 configured to deform the display module 110 to the flat state or the curved state, and the hinge cover 121 configured to cover the hinge unit 122.

The display module 110 is a constituent element for providing an image and a sound to the user. To this end, various types of components for providing the image and the sound may be mounted in the display module 110.

The display module 110 may include a display panel and a display cover 113.

The display panel may be configured to display images to the outside and configured as various displays for displaying images. That is, the display panel may be a flat panel display and provided as any one of a plasma display panel, a liquid crystal display, an organic light-emitting diode display, and a light-emitting diode display. For example, in case that the flat panel display is a liquid crystal display, the display module 110 may include a liquid crystal panel configured to display images, a backlight unit configured to supply light to the liquid crystal panel, the display cover, and the like. In addition, in case that the flat panel display is an organic light-emitting diode display, the display module 110 may include an organic light-emitting diode panel configured to display images, the display cover, and the like.

Meanwhile, for example, the display panel may be provided as a curved display or a flexible display instead of a flat panel display. In addition, the display panel maybe provided as a touch type display.

The display cover 113 is a constituent element configured to cover the display panel. The display cover 113 may be provided as a single cover or a plurality of covers. For example, in case that the display cover is provided as a plurality of covers, the display covers 113 may include a decorative cabinet, a cover bottom, a back cover, and the like. However, the present disclosure is not limited thereto.

A stand mounting hole for mounting the stand 115 may be formed in a rear surface of the display cover 113.

In addition, various interface cables, such as a power cable for providing power to the display module 110 and a cable for providing a sound, may be provided on the rear surface of the display cover 113.

Although not illustrated, a heat dissipation part may be provided on the rear surface of the display cover 113 and disposed below the stand mounting hole to dissipate heat in the display module 110. The heat dissipation part may be formed in a direction facing a front surface of a stand body 115-1 of the stand 115. Therefore, the heat dissipation part may be disposed so as not to be exposed to the outside of the display device 100.

The stand 115 is a constituent element for supporting the display module 110.

The stand 115 may be mounted rearward of the display module 110 and seated on a desk, a table, or the like. The stand 115 may stably support the display module 110. For example, the stand 115 may be disposed rearward of the display module 110 and mounted on a rear surface of the stand fastening part 124. However, the present disclosure is not limited thereto.

The stand 115 may include the stand body 115-1 and a stand base 115-2.

The stand body 115-1 may be mounted rearward of the display module 110. For example, the stand body 115-1 may be disposed rearward of the display module 110 and disposed in a height direction of the display module 110.

For example, the stand body 115-1 may include a front cover, a body base, and a rear cover.

In addition, for example, the stand base 115-2 may be connected to a lower side of the stand body 115-1 and seated on a desk, a table, or the like. In this case, the stand base 115-2 may be detachably connected to the lower side of the stand body 115-1. Therefore, in some aspects of the present disclosure, when the product is shipped, the stand base 115-2 may be separated from the stand body 115-1 for transportation and delivery to an end user or the like.

For example, the stand base 115-2 may be made of a metallic material. This configuration is implemented in consideration of design and rigidity. The stand base 115-2 made of a metallic material may implement an aesthetic external appearance design of the display device 100 and ensure the support rigidity.

Meanwhile, the display deformation drive part 120 is a constituent element for adjusting an angle of the display module 110 to provide an optimal angle when the user or the like uses the display device 100. In addition, the display deformation drive part 120 may connect the display module 110 and the stand 115.

The display deformation drive part 120 may include the hinge unit 122 configured to deform the display module 110 to the flat state or the curved state (or curved surface state), and the hinge cover 121 configured to cover the hinge unit 122.

As described above, the hinge unit 122 may deform the display module 110 to the flat state or the curved state, thereby implementing free-stop bending in the curved state.

For example, the hinge unit 122 may include a 4-torque hinge structure to implement the free-stop bending. For example, the hinge unit 122 may include a first hinge frame 126-1, second hinge frames 126-2, third hinge frames 126-3, first hinge parts 125-1, second hinge parts 125-2, and a plurality of stoppers 140. However, the present disclosure is not limited thereto. The first hinge part 125-1 may be an inner hinge part, and the second hinge part 125-2 may be an outer hinge part.

For example, one second hinge frame 126-2 may be coupled to either side of one first hinge frame 126-1 by means of the first hinge part 125-1. The coupling may be such that the second hinge frame 126-2 is movable (can rotate) with respect to the first hinge part 125-1.

For example, one third hinge frame 126-3 may be coupled to an outer end of each of the second hinge frames 126-2 by means of the second hinge part 125-2. The coupling may be such that the second hinge frame 126-3 is movable (can rotate) with respect to the second hinge part 125-2.

Torque may be generated by the first hinge part 125-1 and the second hinge part 125-2. For example, a torque level may be adjusted by adjusting a surface frictional force between the components fastened to bolts 127 and nuts 129 provided in the first hinge part 125-1 and the second hinge part 125-2. For example, torque may be increased by tightening the bolt 127 and the nut 129, and torque may be decreased by loosening the bolt 127 and the nut 129. A detailed description of this configuration will be described below.

For example, the pair of stoppers 140 may be respectively coupled to outer ends of the third hinge frames 126-3. For example, when the display device 100 is viewed from the rear side, the stoppers 140 may be respectively disposed at upper and lower sides of the outer ends of the third hinge frames 126-3 one by one. However, the present disclosure is not limited thereto. The number and positions of the stoppers 140 may be adjusted by a magnitude of a force applied to unfold the display module 110 in a reverse direction (to the bending direction).

Hereinafter, for convenience of description, the upper and lower sides mean upper and lower sides when viewed from the rear side in a state in which the display device 100 stands upright.

The stopper 140 according to one aspect of the present disclosure may serve to restrict (block) a force applied to unfold the display module 110 in the reverse direction in the curved state. A detailed description of this configuration will be described below.

As described above, the hinge unit 122 according to the first aspect of the present disclosure may include the single first hinge frame 126-1, the two second hinge frames 126-2, the two third hinge frames 126-3, the two first hinge parts 125-1, the two second hinge parts 125-2, and the two pairs of stoppers 140. However, the present disclosure is not limited thereto.

Meanwhile, the hinge cover 121 may cover and protect the hinge unit 122, i.e., the first hinge frame 126-1, the second hinge frames 126-2, the third hinge frames 126-3, the first hinge parts 125-1, the second hinge parts 125-2, and the plurality of stoppers 140.

The display deformation drive part 120 may further include the fastening part 124 fastened to the stand 115 while covering a central portion of the hinge cover 121.

The display deformation drive part 120 may further include handles 123 provided at two opposite sides of the hinge cover 121 and configured to allow the user to apply a physical force to arbitrarily deform the display module 110 to the flat state or the curved state. However, the present disclosure is not limited thereto. For example, the user may pull the two opposite handles 123 forward or push the two opposite handles 123 rearward to arbitrarily deform the display module 110 to the flat state or the curved state in which the display module 110 has any curvature.

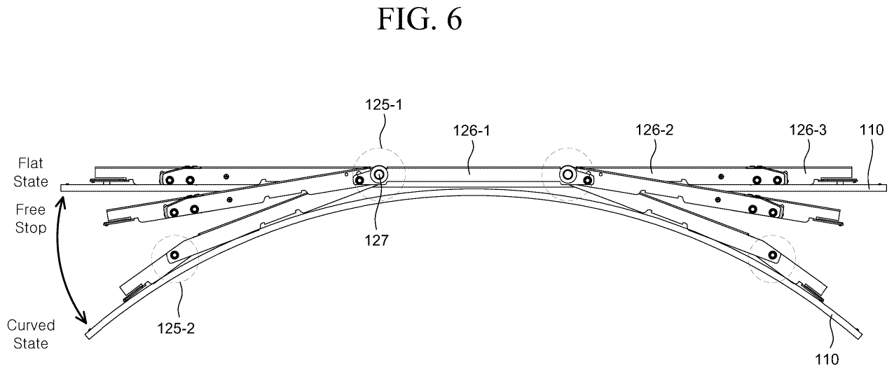

FIG. 6 is a view exemplarily illustrating free-stop bending made by the hinge unit according to some aspects of the present disclosure.

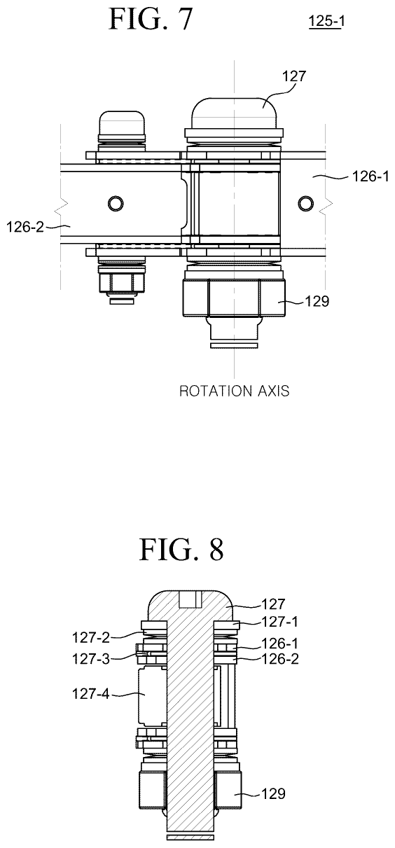

FIG. 7 is an enlarged view of the first hinge part in FIG. 5 according to some aspects of the present disclosure.

FIG. 8 is a view illustrating a part of a cross-section of the first hinge part in FIG. 7 according to some aspects of the present disclosure.

FIG. 6 is a view for explaining free-stop bending made by the hinge unit. FIG. 6 is a view illustrating the display module 110 and the hinge unit 122 on the rear surface of the display module 110 when viewed from the top side, for example, when the viewer is positioned at the left side.

With reference to FIGS. 6 to 8, the display module 110 may freely switch (or freely stop) between the flat state and the curved state by means of the hinge unit 122.

In addition, when the display module 110 freely switches between the flat state and the curved state by means of the hinge unit 122, the user may stop the display module 110 at a desired point (or desired radius of curvature), and the stoppers (140 in FIG. 4) may inhibit the display module 110 from moving to another position.

For example, the curved state of the display module 110 may be implemented by the first hinge frame 126-1, the second hinge frames 126-2, the third hinge frames 126-3, the first hinge parts 125-1, and the second hinge parts 125-2. In particular, the curved state of the display module 110 may be implemented by the first hinge part 125-1 between the first hinge frame 126-1 and the second hinge frame 126-2 and the second hinge part 125-2 between the second hinge frame 126-2 and the third hinge frame 126-3.

As described above, torque may be generated by the first hinge part 125-1 and the second hinge part 125-2. That is, for example, the torque level may be adjusted by adjusting the surface frictional force between the components fastened to the bolts 127 and the nuts 129 provided in the first hinge part 125-1 and the second hinge part 125-2. For example, torque may be increased by tightening the bolt 127 and the nut 129, and torque may be decreased by loosening the bolt 127 and the nut 129.

For example, the display module 110 may be primarily bent at a first curvature by the first hinge part 125-1, and the display module 110 may be secondarily bent at a second curvature by the second hinge part 125-2. The second curvature may be larger than the first curvature.

For example, a plain washer 127-1, a spring washer 127-2, the first hinge frame 126-1, polyoxymethylene POM 127-3, and the second hinge frame 126-2 may be sequentially disposed between the bolt 127 and the nut 129, and the second hinge frame 126-2, POM 127-3, the first hinge frame 126-1, a spring washer 127-2, and a plain washer 127-1 may be disposed in the reverse order at a lower side thereof.

The plain washer 127-1 and the spring washer 127-2 may be components having a flat plate shape and a spring shape and configured to be fitted between a head of a screw or the bolt 127 and the component or structure. The plain washer 127-1 and the spring washer 127-2 may be used to reduce friction between the components or more securely tight the bolt 127.

The POM 127-3 is a type of polymer and has excellent rigidity and strength, high durability, and stable properties even at a high-temperature temperature. The POM 127-3 may be substituted with another material.

In addition, a metal block 127-4 may be inserted between the second hinge frame 126-2 and the second hinge frame 126-2 between the bolt 127 and the nut 129. However, the present disclosure is not limited thereto.

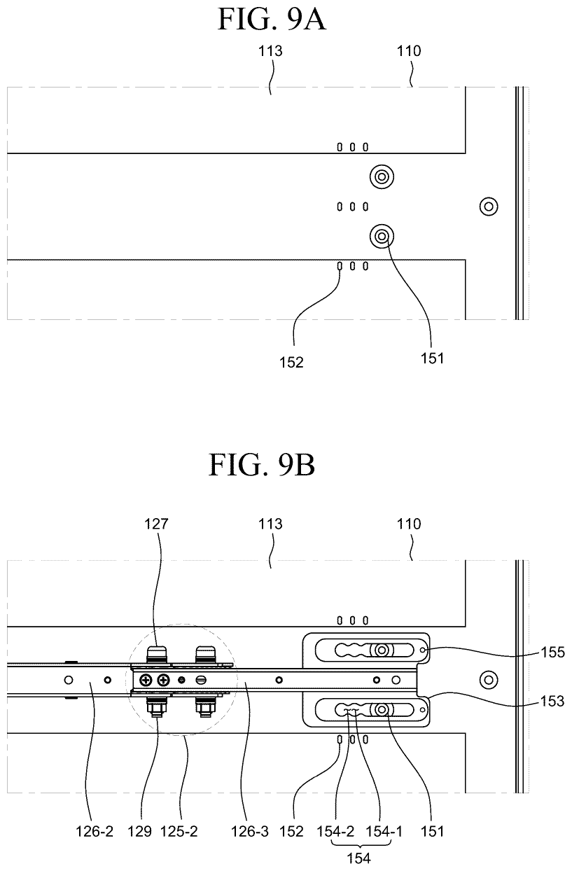

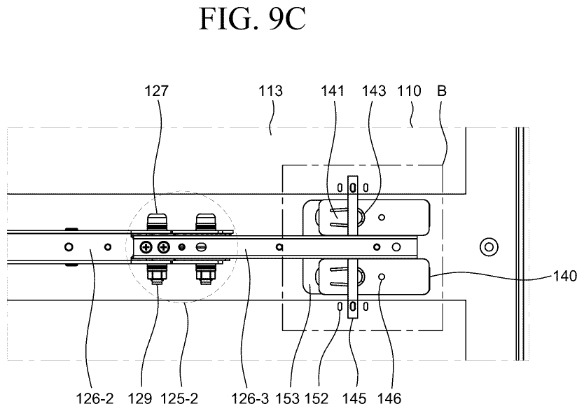

Meanwhile, in the display device of the first aspect of the present disclosure, the plurality of stoppers 140 is coupled to the outer ends of the third hinge frame 126-3 and serves to restrict (block) the force applied to unfold the display module 110 in the reverse direction in the curved state. This configuration will be described in detail with reference to FIGS. 9A to 9C, 10A to 10C, 11A to 11C, 12A, 12B, 13A, and 13B.

FIGS. 9A to 9C are enlarged view of part A in FIG. 4 according to some aspects of the present disclosure.

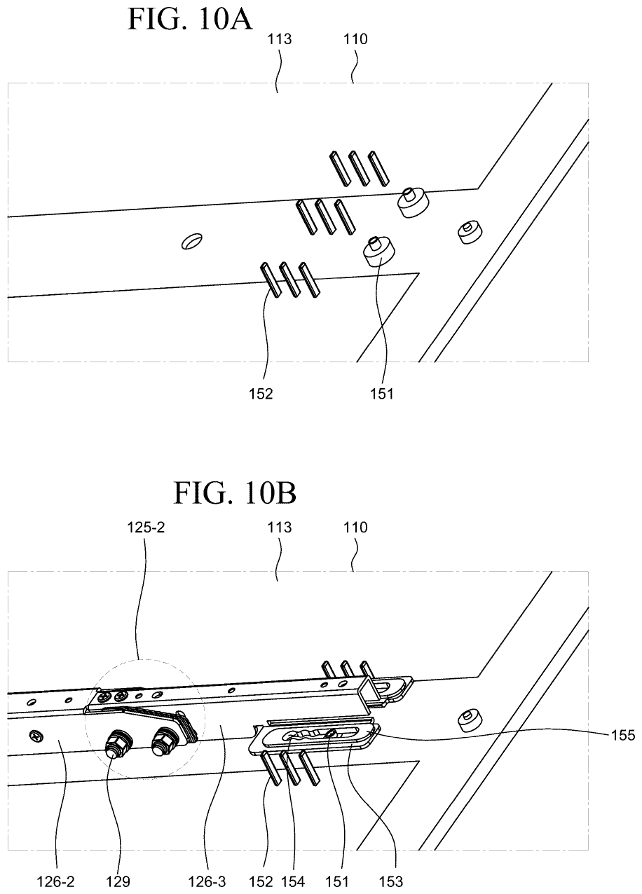

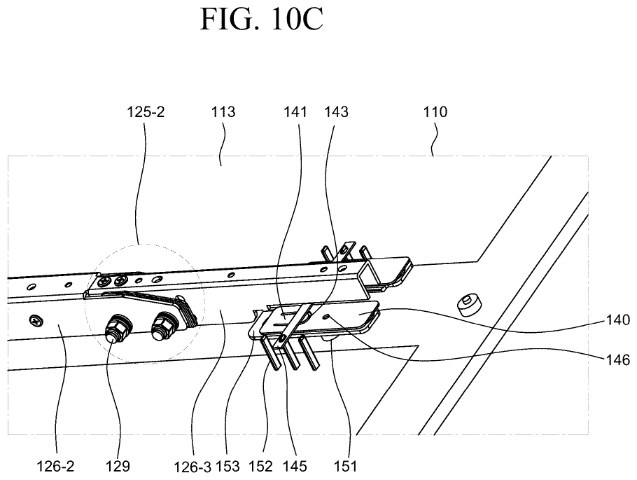

FIGS. 10A to 10C are enlarged perspective views of part A in FIG. 4 according to some aspects of the present disclosure.

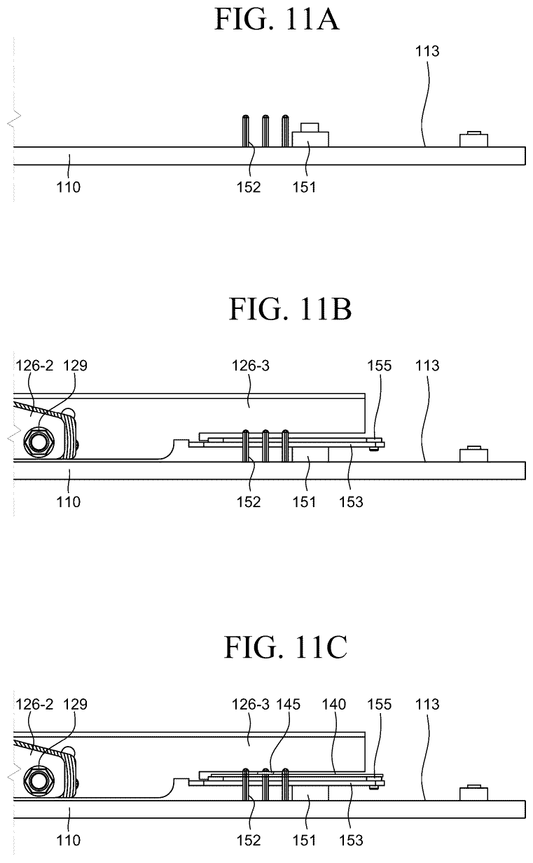

FIGS. 11A to 11C are views illustrating part A in FIG. 4 when viewed from the lateral side according to some aspects of the present disclosure.

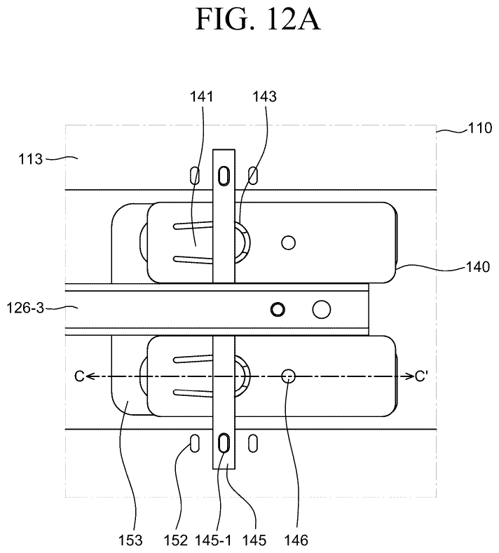

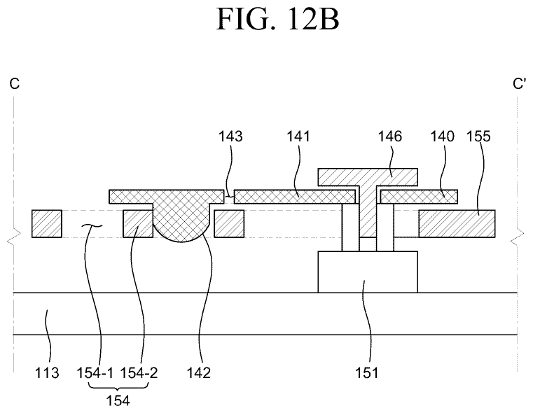

FIG. 12A is an enlarged view of part B in FIG. 9C according to some aspects of the present disclosure.

FIG. 12B is a view illustrating a cross-section taken along line C-C′ in FIG. 12A according to some aspects of the present disclosure.

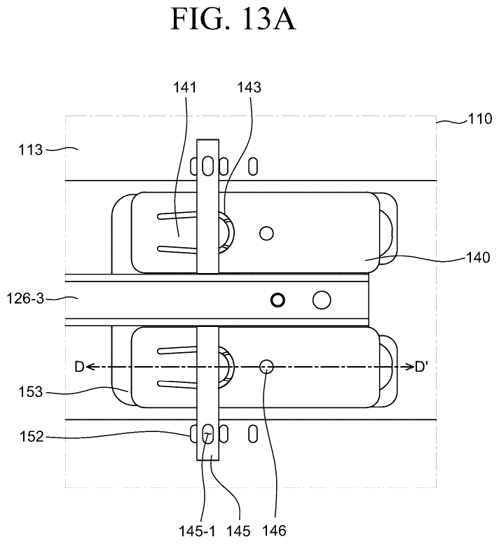

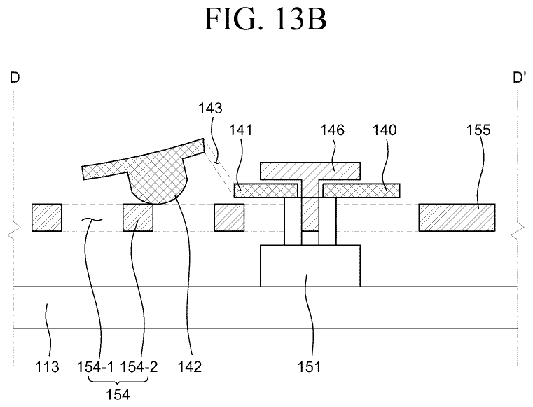

FIG. 13A is an enlarged view of part B in FIG. 9C according to some aspects of the present disclosure.

FIG. 13B is a view illustrating a cross-section taken along line D-D′ in FIG. 13A according to some aspects of the present disclosure.

FIGS. 9A and 10A illustrate an example of a part of the rear surface of the display device 100 in a state in which the hinge unit is removed.

FIGS. 9B and 10B illustrate an example of a part of the rear surface of the display device 100 including the hinge unit 122 and excluding the stopper 140. FIGS. 9C and 10C illustrate an example of a part of the rear surface of the display device 100 including the hinge unit 122.

In addition, FIG. 11A is a view illustrating the display device in a state in which the hinge unit 122 is removed when viewed from the lower side. FIG. 11B is a view illustrating the display device 100 including the hinge unit 122 and excluding the stopper 140 when viewed from the lower side. FIG. 11C is a view illustrating the display device 100 including the hinge unit 122 when viewed from the lower side.

FIGS. 12A and 12B illustrate an example of a part of the display device 100 in the curved display mode. FIGS. 13A and 13B illustrate an example of a part of the display device 100 in the flat display mode.

The present disclosure may include the 4-torque hinge structure including the inner hinge parts and the outer hinge parts to implement the free-stop bending.

Meanwhile, a curvature defect may occur in case that a curvature retention force (i.e., torque) of the hinge unit cannot withstand the force applied to unfold the display module in the reverse direction. In this case, the force applied to unfold the display module in the reverse direction is opposite to the curvature retention force of the hinge unit.

Therefore, the plurality of stoppers may be coupled to the hinge unit of the present disclosure, e.g., the outer ends of the third hinge frame.

With reference to FIGS. 9A to 9C, 10A to 10C, 11A to 11C, 12A, 12B, 13A, and 13B, the hinge unit 122 may include the first hinge frame (126-1 in FIG. 5), the second hinge frames 126-2, the third hinge frames 126-3, the first hinge parts (125-1 in FIG. 5), the second hinge parts 125-2, and the plurality of stoppers 140.

As described above, for example, one second hinge frame 126-2 may be coupled to either side of one first hinge frame 126-1 by means of the first hinge part 125-1.

For example, one third hinge frame 126-3 may be coupled to the outer end of each of the second hinge frames 126-2 by means of the second hinge part 125-2.

For example, the stoppers 140 may be respectively coupled to the outer ends of the third hinge frames 126-3. For example, when the display device is viewed from the rear side, the stoppers 140 may be respectively disposed at the upper and lower sides of the outer ends of the third hinge frames 126-3 one by one to implement the horizontal curvature symmetry. That is, the stoppers 140 may be respectively disposed at the upper and lower sides of the outer ends of the third hinge frames 126-3 one by one to implement the curvature symmetry of the upper and lower sides of the display module 110 with respect to the third hinge frame 126-3. However, the present disclosure is not limited thereto. The number and positions of the stopper may be adjusted depending on the magnitude of the force applied to unfold the display module 110 in the reverse direction (to the bending direction). For example, the pair of upper and lower stoppers 140 may have a horizontally symmetric structure. For example, the pair of stoppers 140, which is disposed at the outer end of the third hinge frame 126-3 at the right side, and the pair of stoppers 140, which is disposed outside the third hinge frame 126-3 at the left side, may have a vertically symmetric structure.

The stopper 140 according to the first aspect of the present disclosure may serve to restrict (block) the force applied to unfold the display module 110 in the reverse direction in the curved state (or curved surface state) of the display module 110.

For example, the stopper 140 may be a thin plate and have a rectangular shape as a whole. However, the present disclosure is not limited thereto.

An elongated semicircular slit (or groove) 143 may be provided inside one side of the stopper 140. A fixing portion 141 surrounded by the slit 143 may move upward or downward, like a flat spring.

As described above, in some aspects of the present disclosure, when the display module 110 changes to the flat state from the curved state in which the display module 110 is bent, the fixing portion 141, which is surrounded by the slit 143 instead of the entire stopper 140, moves upward or downward like the flat spring, which may reduce a force that pushes a polymer plate 155. In addition, it is possible to reduce the force, which pushes the polymer plate 155, by changing a position of an embossed portion 142. As a result, it is possible to suppress noise and abrasion of constituent components, such as the polymer plate 155, caused by repeated bending.

In this case, examples of the method of reducing the force applied to the embossed portion 142 includes a method of reducing the force applied to the embossed portion 142 in the flat state by forming the slit 143 around the embossed portion 142, and a method of reducing the force applied to the embossed portion 142 by increasing a distance between the embossed portion 142 and the fixing portion 141 when energy for bending the flat spring is constant.

For example, the embossed portion 142, which is a protruding structure, may be formed on a lower portion of the fixing portion 141 of the stopper 140, and the embossed portion 142 may also move upward or downward in accordance with the upward or downward movement of the fixing portion 141. In this case, the upward/downward direction means front and rear sides when viewed from the rear side in the state in which the display device stands upright.

For example, the embossed portion 142 may have a circular shape in a plan view. However, the present disclosure is not limited thereto.

The stopper 140 may be fastened to the display cover 113 by a fastening means 146. For example, the stopper 140 may be fastened to a fixing means 151 by the fastening means 146, and the fixing means 151 may be formed on the rear surface of the display cover 113.

For example, the fastening means 146 may include a screw. In addition, for example, the fixing means 151 may include a nut or a press-in threaded insert nut (PEM nut).

The outer ends of the third hinge frames 126-3 may be bent upward and downward and constitute a pair of support portions 153. For example, the support portion 153 has a rectangular shape as a whole. A slot may be formed in the support portion 153 and have a shape elongated in a longitudinal direction.

The polymer plate 155, which has a shape (form) similar to that of the support portion 153, may be disposed on the support portion 153, and the stopper 140 may be disposed on the polymer plate 155.

Individually, the polymer plate 155 is attached to the support portion 153 of the third hinge frame 126-3, and the stopper 140 is fastened to the display cover 113. Therefore, the third hinge frame 126-3 and the polymer plate 155, which is attached to the support portion 153 of the third hinge frame 126-3, may move leftward and rightward relative to the display cover 113 and the stopper 140, which is fastened to the display cover 113, in response to the flat state or the curved state of the display module 110.

For example, the polymer plate 155 may have a rectangular shape as a whole. Similar to the support portion 153, the polymer plate 155 may have a slot 154 formed in the polymer plate 155 and having a shape elongated in the longitudinal direction.

For example, the polymer plate 155 may include polyoxymethylene (POM). However, the present disclosure is not limited thereto.

For example, the slot 154 of the polymer plate 155 may correspond to the slot of the support portion 153. The slot of the support portion 153 may be larger than the slot 154 of the polymer plate 155.

For example, the slot 154 of the polymer plate 155 may include a plurality of circular first holes 154-1. That is, the circular first holes 154-1 are formed at predetermined intervals in the longitudinal direction in the polymer plate 155, such that the slot 154 having an elongated shape may be formed. In this case, the slot 154 may include the first holes 154-1 and a second hole 154-2 formed between the first holes 154-1. The second hole 154-2 may have a smaller width than the first hole 154-1.

For example, the first hole 154-1 may have a width or diameter to a degree to which the embossed portion 142 is inserted into the first hole 154-1. In contrast, the second hole 154-2 may have a width smaller than a width of the embossed portion 142.

Therefore, in case that the curved display mode is implemented by manipulating the display deformation drive part, the embossed portion 142 is positioned in the first hole 154-1 in a predetermined (or particular) curvature state, such that the embossed portion 142 may be inserted and fixed into the first hole 154-1. In this case, it is possible to restrict the force applied to unfold the display module 110 in the reverse direction, such that the display module 110 may be kept in the predetermined (or particular) curvature state (see FIGS. 12A and 12B).

In contrast, in case that the flat display mode is made or the display module 110 has a curvature between particular curvatures by manipulating the display deformation drive part, the embossed portion 142 is positioned in the second hole 154-2, such that the embossed portion 142 may be positioned on the polymer plate 155 by being lifted upward without being inserted and fixed into the second hole 154-2. In this case, the display module 110 may be kept in the flat state or slip toward the periphery to be in the curved state (see FIGS. 13A and 13B).

As described above, the fixing portion 141 and the embossed portion 142 of the stopper 140 and the slot 154 of the polymer plate 155, according to some aspects of the present disclosure, may constitute a primary curvature retention structure that restricts the force applied to unfold the display module 110 in the reverse direction.

The plurality of first holes 154-1 may be formed at predetermined (or particular) positions to implement a particular curvature of the display module 110. The plurality of first holes 154-1 may serve to restrict the force applied to unfold the display module 110 in the reverse direction as the embossed portion 142 is inserted into (or caught by) the first hole 154-1.

Meanwhile, the display device of the present disclosure may include a link structure configured to synchronize the pair of upper and lower stoppers 140 and inhibit the stoppers 140 from being distorted. That is, in case that the link structure is not provided in case that the stopper 140 and the display module 110 are fastened at a single point, the stoppers 140 may be distorted with respect to the fastening point (i.e., the fastening means 146).

Therefore, for example, in the display device of the present disclosure, a link 145 may be attached to upper portions of the pair of upper and lower stoppers 140 in a direction in which the link 145 traverses the pair of stoppers 140. For example, the link 145 may be attached to upper portions of the fixing portions 141 of the stoppers 140 that are opposite to the embossed portions 142.

As described above, the embossed portion 142, which is a protruding structure, may be formed on the lower portion of the fixing portion 141 of the stopper 140, and the link 145 may be attached to the upper portion of the fixing portion 141 of the stopper 140 opposite to the embossed portion 142, such that the embossed portion 142 and the link 145 may move upward and downward in accordance with the upward and downward movements of the fixing portion 141. In this case, the upward/downward direction means front and rear sides when viewed from the rear side in the state in which the display device stands upright.

For example, the link 145 may have a bar shape. However, the present disclosure is not limited thereto.

The link 145 may serve to suppress the distortion of the stopper 140 by synchronizing the pair of upper and lower stoppers 140 when the stoppers 140 operate. If the stopper 140 is distorted, an operation defect and an insertion defect of protruding structures 152 occur.

Therefore, insertion holes 145-1 may be formed at two opposite ends of the link 145 of the present disclosure, and the protruding structures 152 may be inserted into the insertion holes 145-1. In addition, the insertion hole 145-1 may also be formed at a center of the link 145. However, the present disclosure is not limited thereto.

In this case, the plurality of protruding structures 152 may be formed on the rear surface of the display cover 113 and disposed at positions corresponding to the insertion holes 145-1. The drawings illustrate an example in which three protruding structures 152 are disposed at each of the upper, lower, and central portions. However, the present disclosure is not limited thereto. The number of protruding structures 152 disposed to implement a particular curvature may vary.

For example, the protruding structure 152 may be disposed on the rear surface of the display cover 113 and have a height to a degree to which the protruding structure 152 penetrates the insertion hole 145-1.

For example, the protruding structure 152 may be integrated with the display cover 113. That is, the protruding structure 152 and the display cover 113 may be integrated, like a unified material, such that a component material may be simplified and unified.

For example, the plurality of protruding structures 152 may be disposed at intervals between the plurality of first holes 154-1. However, the present disclosure is not limited thereto.

That is, the position of the protruding structure 152 may be determined depending on a free-stop position. In addition, the number of protruding structures 152 may be determined depending on a stopping reinforcement force.

As described above, the link 145, together with the protruding structure 152, may constitute a secondary curvature retention structure for minimizing bending rigidity of the embossed portion 142.

Therefore, in case that the curved display mode is implemented by manipulating the display deformation drive part, a slip occurs between the display cover 113 and the third hinge frame 126-3, and the fixing portion 141 of the stopper 140 moves upward or downward. In addition, the link 145 attached to the upper portion of the fixing portion 141 also moves upward or downward. In this case, as the link 145 moves upward or downward, the protruding structure 152 may be inserted and fixed into the insertion hole 145-1 of the link 145. Therefore, in this case, it is possible to restrict the force applied to unfold the display module 110 in the reverse direction, such that the display module 110 may be kept in the predetermined (or particular) curvature state (see FIGS. 12A and 12B).

In this case, in case that the secondary curvature retention structure is applied, the embossed portion 142 may perform the function of moving the secondary curvature retention structure upward or downward rather than the stopper function.

In contrast, in case that the flat display mode is made or the display module 110 has a curvature between particular curvatures by manipulating the display deformation drive part, the embossed portion 142 is positioned in the second hole 154-2, such that the embossed portion 142 may be positioned on the polymer plate 155 by being lifted upward without being inserted and fixed into the second hole 154-2. In this case, the link 145 attached to the upper portion of the fixing portion 141 is also lifted upward and positioned between the protruding structures 152. Therefore, the display module 110 may be kept in the flat state or slip toward the periphery to be in the curved state (see FIGS. 13A and 13B).

The drawings illustrate an example in which the single link 145 constitutes the secondary curvature retention structure. However, the present disclosure is not limited thereto. Two or more links 145 may be disposed. In this case, the protruding structures 152 disposed at two or more points may be inserted into two or more links 145.

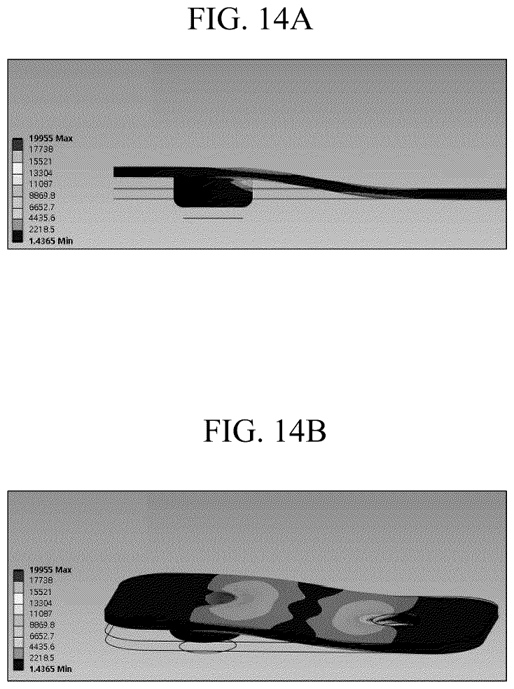

FIGS. 14A and 14B are views illustrating simulation results showing examples of equivalent stress of a comparative example according to some aspects of the present disclosure.

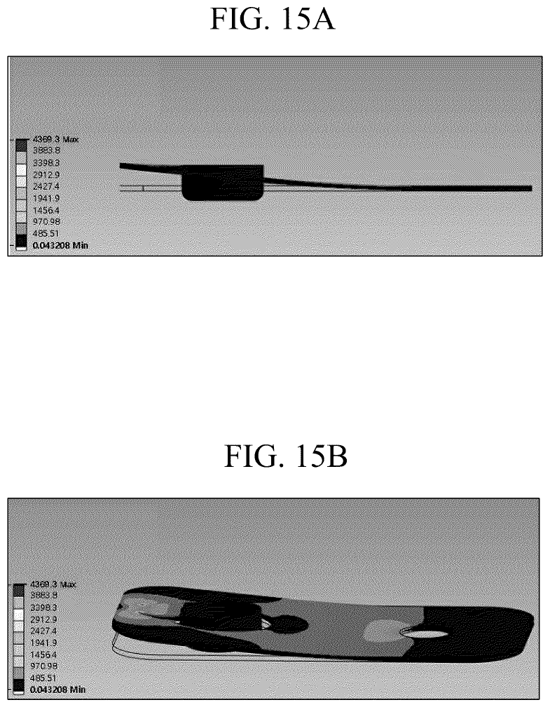

FIGS. 15A and 15B are views illustrating simulation results showing examples of equivalent stress of a comparative example according to some aspects of the present disclosure.

In this case, a boundary condition of the simulation is a case in which the embossed portion is moved upward by about 5.0 mm.

For reference, equivalent stress refers to a concept used to evaluate an overall stress state of a material or structure. The equivalent stress may be represented by a single scalar value made by combining multiple stresses in a complex stress situation that occurs when a three-dimensional object is subjected to various loads.

With reference to FIGS. 14A and 14B, it may be seen that the maximum stress is about 19, 955 MP in the case of the comparative example, and the maximum stress is measured at the periphery of the embossed portion and the periphery of the fixing portion.

In contrast, with reference to FIGS. 15A and 15B, it may be seen that in the case of the this non-limiting comparative example, the maximum stress is about 4, 369.3 MP at the periphery of the embossed portion and about 2, 570.3 MP at the periphery of the fixing portion, and the maximum stress is significantly decreased in comparison with the maximum stress in the comparative example.

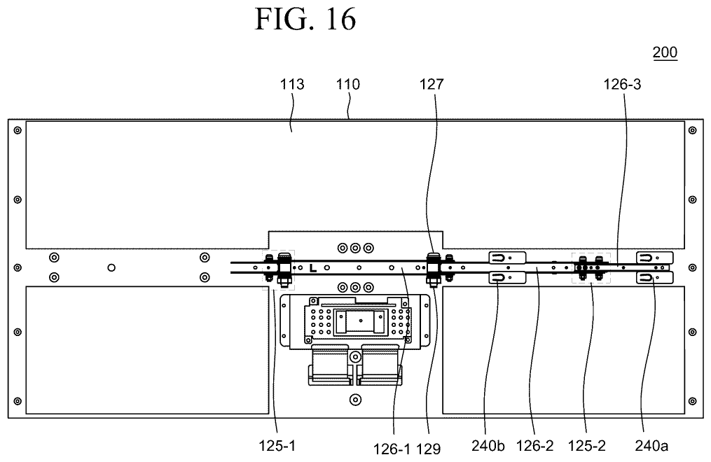

Meanwhile, in the present disclosure, the stoppers may not only be disposed at the outer ends of the third hinge frame but also be additionally disposed on the second hinge part. This configuration will be described with reference to FIG. 16.

FIG. 16 is a rear view illustrating a display device according to some aspects of the present disclosure.

The example in FIG. 16 is substantially identical in configuration to aspects of the present disclosure described with reference to FIGS. 3 to 13A and 13B, except that a second stopper 240b is also additionally on a second hinge part 126-2. Therefore, the same reference numerals are assigned to the same components, and a description thereof will be omitted.

FIG. 16 is a view illustrating a rear surface of a display device 200 according to the second aspect of the present disclosure that does not include the stand 115, the hinge cover 121, and the stand fastening part 124. For convenience of description, FIG. 16 illustrates a state in which the left side of the hinge unit is excluded.

With reference to FIG. 16, the display device 200 may include the display module 110, the stand 115, and the display deformation drive part 120.

The display deformation drive part may include the hinge unit configured to deform the display module 110 to the flat state or the curved state, and the hinge cover 121 configured to cover the hinge unit. A detailed description of the display module 110, the hinge unit 122, and the hinge cover 121 may be the same as that described above with reference to FIGS. 3 to 13A and 13B.

As described above, for example, the hinge unit may include the first hinge frame 126-1, the second hinge frames 126-2, the third hinge frames 126-3, the first hinge parts 125-1, the second hinge parts 125-2, and a plurality of stoppers 240a and 240b.

For example, one second hinge frame 126-2 may be coupled to either side of one first hinge frame 126-1 by means of the first hinge part 125-1 as described above.

For example, one third hinge frame 126-3 may be coupled to the outer end of each of the second hinge frames 126-2 by means of the second hinge part 125-2 as described above.

For example, the pair of first stoppers 240a may be respectively coupled to the outer ends of the third hinge frames 126-3. That is, for example, when the display device 200 is viewed from the rear side, the first stoppers 240a may be respectively disposed at the upper and lower sides of the outer ends of the third hinge frames 126-3 one by one. However, the present disclosure is not limited thereto. The number and positions of the stoppers 240a may be adjusted by a magnitude of a force applied to unfold the display module 110 in the reverse direction (to the bending direction).

In some examples, a pair of second stoppers 240b may be respectively coupled to the second hinge frames 126-2. For example, when the display device 200 is viewed from the rear side, the second stoppers 240b may be respectively disposed at the upper and lower sides of the second hinge frames 126-2 one by one. However, the present disclosure is not limited thereto. The number and positions of the second stoppers 240b may be adjusted by a magnitude of a force applied to the display module 110 to unfold the display module 110 in the reverse direction.

For example, the first stopper 240a and the second stopper 240b may be disposed at the same horizontal position.

Detailed structures of the first stopper 240a and the second stopper 240b may be the same as described above with reference to FIGS. 3 to 13A and 13B.

As described above, the hinge unit may include the single first hinge frame 126-1, the two second hinge frames 126-2, the two third hinge frames 126-3, the two first hinge parts 125-1, the two second hinge parts 125-2, the two pairs of first stoppers 240a, and the two pairs of second stoppers 240b. However, the present disclosure is not limited thereto.

Meanwhile, in the present disclosure, a stopper structure may be formed by additionally extending an end of the third hinge frame. This configuration will be described in detail with reference to the drawings.

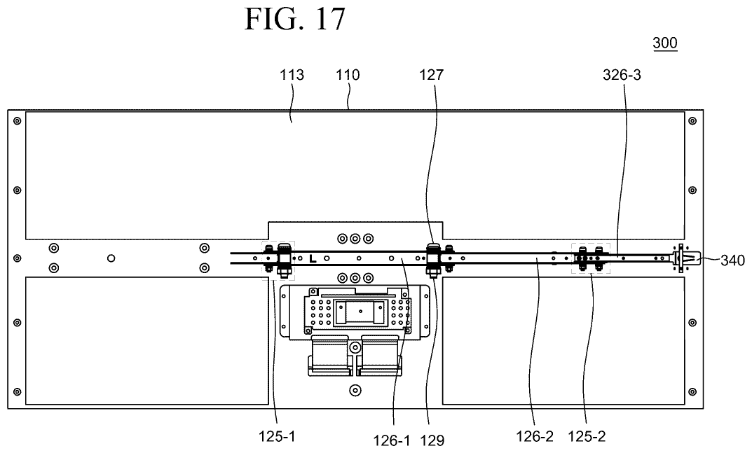

FIG. 17 is a rear view illustrating a display device according to some aspects of the present disclosure.

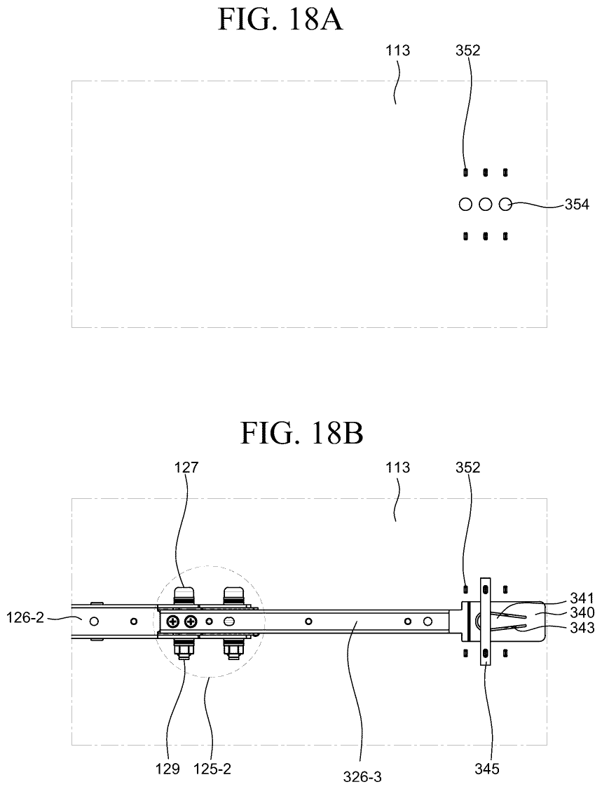

FIGS. 18A and 18B are rear views illustrating a part of a rear surface of the display device according to some aspects of the present disclosure.

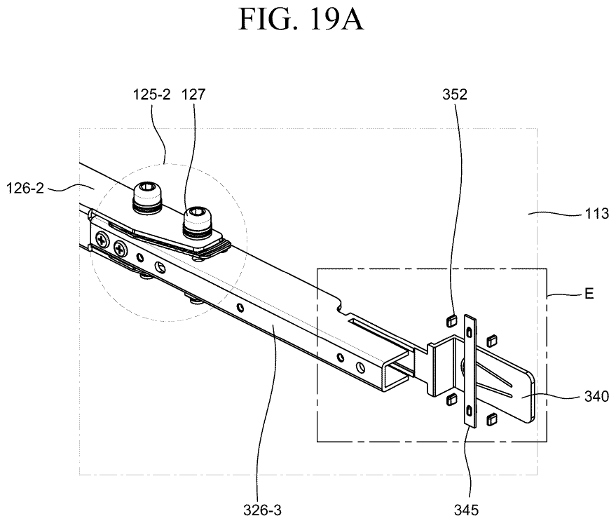

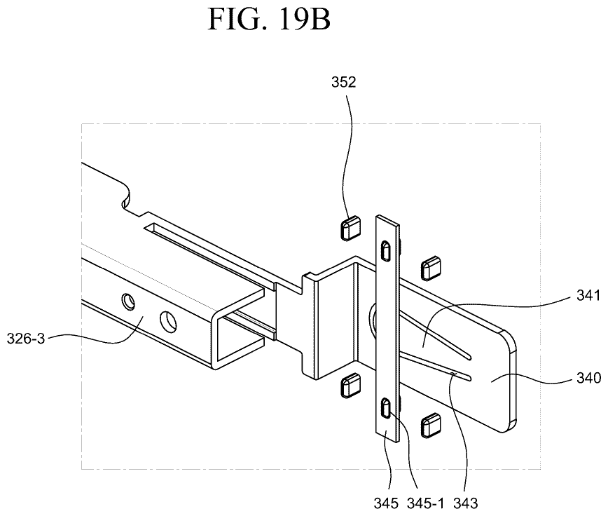

FIGS. 19A and 19B are perspective views illustrating a part of the rear surface of the display device according to some aspects of the present disclosure.

FIG. 17 is a view illustrating a rear surface of a display device 300 that does not include the stand 115, the hinge cover 121, and the stand fastening part 124. For convenience of description, FIG. 17 illustrates a state in which the left side of the hinge unit is excluded.

FIG. 18A illustrates an example of a part of the rear surface of the display device in a state in which the hinge unit is removed.

FIGS. 18B and 19A illustrate an example of a part of the rear surface of the display device including the hinge unit 122. FIG. 19B illustrates enlarged part E in FIG. 19A.

Example aspect described with reference to FIGS. 17, 18A, 18B, 19A, and 19B is substantially identical in configuration to aspects described with reference to FIGS. 3 to 13A and 13B, except that a stopper 340 is formed by extending an end of a third hinge frame 326-3. Therefore, the same reference numerals are assigned to the same components, and a description thereof will be omitted.

With reference to FIGS. 17, 18A, 18B, 19A, and 19B, display device 300 according to aspects of the present disclosure may include the display module 110, the stand 115, and the display deformation drive part 120.

For example, the hinge unit may include the first hinge frame 126-1, the second hinge frames 126-2, the third hinge frames 326-3, the first hinge parts 125-1, the second hinge parts 125-2, and the stoppers 340.

As described above, for example, one second hinge frame 126-2 may be coupled to either side of one first hinge frame 126-1 by means of the first hinge part 125-1.

For example, one third hinge frame 326-3 may be coupled to the outer end of each of the second hinge frames 126-2 by means of the second hinge part 125-2.

For example, the stopper 340 may be formed by extending the outer end of each of the third hinge frames 326-3 in a length direction. As described above, the stopper 340 may be integrated with the third hinge frame 326-3. That is, the stopper 340 and the third hinge frame 326-3 may be integrated, like a unified material, such that a component material may be simplified and unified.

For example, a lower side of the outer end of the third hinge frame 326-3 may extend in the length direction and be bent twice, such that the bent end may define the stopper 340.

In some aspects, the end of the third hinge frame 326-3 constitutes the stopper 340, which may inhibit the stoppers from being disposed to be horizontally asymmetric. Therefore, it is possible to suppress a problem with a horizontally asymmetric curvature of the display module 110.

An elongated semicircular slit (or groove) 343 may be provided inside one side of the stopper 340. A fixing portion 341 surrounded by the slit 343 may move upward or downward, like a flat spring. In this case, the slit 343 has a semicircular shape opened at an outer side thereof. However, the present disclosure is not limited thereto.

In addition, for example, an embossed portion, which is a protruding structure, may be formed on a lower portion of the fixing portion 341 of the stopper 340, and the embossed portion may also move upward or downward in accordance with the upward or downward movement of the fixing portion 341.

For example, a plurality of circular holes 354 may be provided in the rear surface of the display cover 113 and disposed at predetermined (or particular) intervals.

For example, the hole 354 may have a width or diameter to a degree to which the embossed portion is inserted into the hole 354.

Therefore, in case that the curved display mode is implemented by manipulating the display deformation drive part, the embossed portion is positioned in the hole 354 in a particular curvature state, such that the embossed portion may be inserted and fixed into the hole 354. In this case, it is possible to restrict the force applied to unfold the display module 110 in the reverse direction, such that the display module 110 may be kept in the particular curvature state.

In contrast, in case that the flat display mode is made or the display module 110 has a curvature between particular curvatures by manipulating the display deformation drive part, the embossed portion is positioned between the holes 354, such that the embossed portion is lifted upward and positioned on the rear surface of the display cover 113 without being inserted and fixed into the hole 354. In this case, the display module 110 may be kept in the flat state or slip toward the periphery to be in the curved state.

As described above, the plurality of holes 354 and the fixing portion 341 and the embossed portion of the stopper 340 may constitute a primary curvature retention structure that restricts the force applied to unfold the display module 110 in the reverse direction.

The plurality of holes 354 may be formed at predetermined (or particular) positions to implement a particular curvature of the display module 110.

For example, in the display device 300, a link 345 may be attached to an upper portion of the stopper 340 in a direction in which the link 345 traverses the stopper 340. For example, the link 345 may be attached to upper portion of the fixing portion 341 of the stopper 340 opposite to the embossed portion 142.

Therefore, the embossed portion, which is a protruding structure, may be formed on the lower portion of the fixing portion 341 of the stopper 340, and the link 345 may be attached to the upper portion of the fixing portion 341 of the stopper 340 opposite to the embossed portion, such that the embossed portion and the link 345 may move upward and downward in accordance with the upward and downward movements of the fixing portion 341.

For example, the link 345 may have a bar shape. However, the present disclosure is not limited thereto.

In addition, insertion holes 345-1 may be formed at two opposite ends of the link 345 of the present disclosure, and protruding structures 352 may be inserted into the insertion holes 345-1.

In this case, the plurality of protruding structures 352 may be formed on the rear surface of the display cover 113 and disposed at positions corresponding to the insertion holes 345-1. The drawings illustrate an example in which three protruding structures 352 are disposed at each of the upper and lower portions. However, the present disclosure is not limited thereto. The number of protruding structures 352 disposed to implement a or particular curvature may vary.

For example, the protruding structure 352 may be disposed on the rear surface of the display cover 113 and have a height to a degree to which the protruding structure 352 penetrates the insertion hole 345-1.

For example, the plurality of protruding structures 352 may be disposed at intervals between the plurality of holes 354. However, the present disclosure is not limited thereto.

As described above, the link 345, together with the protruding structure 352, may constitute a secondary curvature retention structure for minimizing bending rigidity of the embossed portion.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

Claim language or other language reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, or A and B and C. The language “at least one of” a set and/or “one or more” of a set does not limit the set to the items listed in the set. For example, claim language reciting “at least one of A and B” or “at least one of A or B” can mean A, B, or A and B, and can additionally include items not listed in the set of A and B.

What is claimed is:

1. A display device comprising:
a display module; and
a hinge component configured to enable the display module to switch between being in a flat state or a curved state, the hinge component including:
at least one hinge frame;
at least one hinge component around which the at least one hinge frame is configured to rotate to allow the display module to switch between the flat state and the curved state; and
at least one stopper at each of two ends of the hinge component configured to maintain the display module in the flat state, the curved state, or an intermediary state in between the flat state and the curved state.

2. The display device of claim 1, further comprising:
a pair of bolt and nut for each of the at least one hinge component, the pair of bolt and nut being configured to allow for adjustment of torque applied for maintaining the flat state, the curved state, and the intermediary state.

3. The display device of claim 1, wherein the at least one stopper includes a pair of a lower stopper and an upper stopper.

4. The display device of claim 3, wherein each of the lower stopper and the upper stopper comprise:
a fixing portion; and
a slit, wherein the slit and the fixing portion are configured to maintain the display module in the flat state, the curved state, or the intermediary state in between the flat state and the curved state.

5. The display device of claim 4, wherein the slit has an elongated semi-circular shape.

6. The display device of claim 4, wherein the fixing portion is configured to move in a first direction that is perpendicular to a direction in which the display module moves between the flat state and the curved state.

7. The display device of claim 4, further comprising:
an embossed portion, wherein the slit is formed around the embossed portion.

8. The display device of claim 7, wherein the fixing portion and the embossed portion are configured to move in a first direction that is perpendicular to a direction in which the display module moves between the flat state and the curved state.

9. The display device of claim 1, wherein the at least one hinge frame includes multiple independently movable hinge frames each of which can rotate around one or more of the at least one hinge component to enable the display module to switch between the flat state and the curved state.

10. The display device of claim 1, further comprising:
a hinge cover configured to cover the hinge component; and
a pair of handles, each of which is coupled to one end of the hinge cover for moving the display module between the flat state and the curved state.

11. A device comprising:
a plurality of parts coupled together via a plurality of hinges to enable moving a display module between a flat state and a curved state, wherein the plurality of parts are independently movable; and
at least one stopper attached to the plurality of parts, the at least one stopper being configured to maintain the display module in the flat state, the curved state, or an intermediary state in between the flat state and the curved state.

12. The device of claim 11, wherein the plurality of parts comprises:
a first part at a right end of the device;
a second part at a left end of the device;
a middle part at a center of the device;
a third part between the middle part and the first part; and
a fourth part between the middle part and the second part.

13. The device of claim 12, wherein the at least one stopper comprises:
a first stopper attached to the first part;
a second stopper attached to the second part;
a third stopper attached to the third part; and
a fourth stopper attached to the fourth part.

14. The device of claim 13, wherein each of the first stopper, the second stopper, the third stopper, and the fourth stopper includes a pair of stoppers.

15. The device of claim 12, wherein the at least one stopper is formed as an extension of a respective outer end of each of the first part and the second part.

16. The device of claim 15, wherein the respective outer end is bent to form the at least one stopper.

17. The device of claim 16, wherein the at least one stopper includes:
a slit formed on the at least one stopper; and
a fixing portion surrounded by the slit and configured to move in a first direction that is perpendicular to a direction in which the display module moves between the flat state and the curved state.

18. The device of claim 11, wherein the device is coupled to a backend of the display module to move the display module between the flat state and the curved state.

19. The device of claim 11, wherein a pair of handles are attached to ends of the device to enable moving the display module between the flat state and the curved state.

20. The device of claim 11, wherein the device is coupled to a stand for holding the display module.

21. The display device of claim 3, wherein the lower stopper and the upper stopper have a horizontally symmetric structure, and
wherein the pair of stoppers has a vertically symmetry with respect to at least one other pair of stoppers of the hinge component.

22. The device of claim 12, wherein an outer end of the first part is bent upward and downward to define a pair of support portions,
wherein each support portion of the pair of support portions has a rectangular shape, and
wherein a first slot is formed in the support portion and has a shape elongated in a longitudinal direction.

23. The device of claim 22, wherein a polymer plate is disposed on an upper portion of the support portion, and the at least one stopper is disposed on an upper portion of the polymer plate.

24. The device of claim 23, wherein the polymer plate has a rectangular shape, and a second slot is formed in the polymer plate and has a shape elongated in a longitudinal direction,
wherein the second slot is positioned to correspond to the first slot, and
wherein the second slot is larger in size than the first slot.

25. The device of claim 24, wherein circular first holes are provided in the polymer plate and disposed at predetermined intervals in a longitudinal direction to define the second slot,
wherein the second slot includes the circular first holes and a plurality of second holes provided between the plurality of first holes, and
wherein the second hole has a smaller width than the first hole.

26. The device of claim 25, wherein in case of the curved state, an embossed portion is positioned in the first hole in a predetermined curvature state, such that the embossed portion is inserted and fixed into the first hole, and
wherein in case the flat state or the intermediary state is implemented, the embossed portion is positioned in the second hole, such that the embossed portion is lifted upward and positioned on the polymer plate without being inserted and fixed into the second hole.

27. The device of claim 26, further comprising:
a link attached to upper portions of the pair of stoppers in a direction in which the link traverses the pair of stoppers,
wherein the link is attached to the upper portion of the fixing portion opposite to the embossed portion.

28. The device of claim 27, further comprising:
a plurality of protruding structures protruding from a rear surface of the display module,
wherein insertion holes are provided at two opposite ends of the link, and the protruding structures are inserted into the insertion holes.

29. The device of claim 28, wherein the protruding structure is disposed on the rear surface of the display module and has a height to a degree to which the protruding structure penetrates the insertion hole, and
wherein the plurality of protruding structures is disposed at intervals between the plurality of first holes.

30. The device of claim 28, wherein when in the curved state, the link moves upward or downward together with the fixing portion when the fixing portion moves upward or downward, such that the protruding structures are inserted and fixed into the insertion holes of the link, and
wherein when in the intermediary state or the flat state, the link attached to the upper portion is lifted upward and positioned between the protruding structures.
